(19) United States
(12) Patent Application Publication
(10) Pub. No.: US 2013/0285136 A1
(43) Pub. Date: Oct. 31, 2013

(54) Schottky diode with enhanced breakdown voltage

(71) Applicants: Chin-Hsien LU, Hsinchu (TW); Shuo-Lun TU, Hsinchu (TW); Chin-Wei CHANG, Kaohsiung (TW); Ching-Lin CHAN, Yunlin County (TW); Ming-Tung LEE, Taoyuan County (TW)

(72) Inventors: Chin-Hsien LU, Hsinchu (TW); Shuo-Lun TU, Hsinchu (TW); Chin-Wei CHANG, Kaohsiung (TW); Ching-Lin CHAN, Yunlin County (TW); Ming-Tung LEE, Taoyuan County (TW)

(73) Assignee: MACRONIX INTERNATIONAL CO., LTD., Hsinchu (TW)

(21) Appl. No.: 13/456,199

(22) Filed: Apr. 25, 2012

(51) Int. Cl. H01L 27/06; H01L 21/336; H01L 29/872

(52) U.S. Cl. 257/328; 257/471; 438/237; 257/E29.338; 257/E27.016; 257/E21.417

(57) ABSTRACT

An apparatus of and method for making enhanced Schottky diodes having p-body regions operable to pinch a current flow path in a high-voltage n-well region and field plate structures operable to distribute an electric potential of the Schottky diode allow for a device with enhanced breakdown voltage properties. N-well regions implanted into the substrate over a p-type epitaxial layer may act as an anode of the Schottky diode and n-type well regions implanted in the high-voltage n-well regions may act as cathodes of the Schottky diode. The Schottky diode may also be used as a low-side mosfet structure device.

### TECHNICAL FIELD

This disclosure relates generally to schottky diodes and processes for manufacturing schottky diodes and, more specifically, relates to schottky diodes with enhanced breakdown voltages that may easily be integrated into standard CMOS technologies.

### BACKGROUND

FIG. 1A is a schematic diagram illustrating a conventional buck-converter circuit in a reverse blocking state 100, and FIG. 1B is a schematic diagram illustrating a conventional buck-converter circuit in a forward conducting state 150. The buck-converter circuit includes a voltage source 102, body diode 104, high side MOSFET 106, low side MOSFET 108, Schottky diode 110, inductor 112, capacitors 114, and resistor 116. In the reverse blocking state 100, no current flows through the Schottky diode 110 as the inductor 112 is charged based on the potential V2 across the body diode 104. In the forward conducting state 150, both the body diode 104 and the Schottky diode 110 provide a current path for the inductor 112.

In a conventional buck-convertor circuit, the turn-on voltage of the body diode 104 is relatively high, and the switching speed of the body diode 104 is relatively slow. The Schottky diode 110, in contrast, has a relatively good turn-on voltage and switching speed, but conventional Schottky diodes have a low breakdown voltage. Accordingly, the conventional Schottky diode 110 will provide an advantage of minimizing power loss associated with the body diode 104 but cannot sustain the higher voltages used to charge the inductor 112 due to the low breakdown voltage.

Schottky diodes suffer from similar complications and drawbacks in other circuit configurations. Accordingly, what is needed is a Schottky diode with enhanced breakdown voltage properties.

### BRIEF SUMMARY

Disclosed herein are enhanced Schottky diode structures and methods for manufacturing the enhanced Schottky diode structures. The Schottky diode structures may include one or more p-body regions operable to pinch a current flow path in high-voltage n-well regions and one or more one or more field-plate structures operable to distribute an electric potential of the schottky diode.

According to an aspect, the Schottky diodes may further include a silicon substrate and a p-type epitaxial layer formed at a first depth of the silicon substrate.

According to another aspect, the Schottky diodes may have one or more of the high-voltage n-well regions implanted in the substrate over the p-type epitaxial layer, and each of the high-voltage n-well regions may then operate as the anode of the Schottky diode; and may also have an n-type well region implanted in each of the one or more high-voltage n-well regions, and the n-type well regions may then operate as the cathodes of the Schottky diode.

According to another aspect, the Schottky diode may further include oxide layer regions formed over a portion of the substrate; field oxide (FOX) isolation layer regions formed over portions of the high-voltage n-well regions and n-well regions; and a gate oxide thermal layer regions formed over portions of the substrate.

According to another aspect, the Schottky diode may have one or more poly field plates at least partially formed over one or more of the FOX isolation layer regions, one or more of the high-voltage n-well regions, and the substrate. The poly field plates may be the field-plate structures operable to distribute an electric potential of the Schottky diode.

According to another aspect, the Schottky diode may also have p-type regions implanted into the substrate between high-voltage n-well regions. The p-type regions may then act as the p-body regions operable to pinch the current flow path in the high-voltage n-wells.

According to anther aspect, the Schottky diode has an n-p region implanted into each of the n-well regions, forming an Ohmic contact for the cathode of the Schottky diode; a p-p region implanted into each of the p-body regions, forming an Ohmic contact for the p-body regions of the Schottky diode; a dielectric layer formed over the substrate; and metal structures formed over the dielectric providing a connection pathway for the Schottky diode.

According to another aspect, the Schottky diode may operate as a low-side mosfet structure. For example, one cathode of the Schottky diode may act as the drain of the low-side mosfet structure, the field-plate structure may act as the gate of the low-side mosfet structure, and the p-body regions may operate to pinch the current flow path in the high-voltage n-wells and may act as the bulk of the low-side mosfet structure.

Methods for manufacturing a Schottky diode may include providing a silicon substrate and forming a p-type epitaxial layer at a first depth of the silicon substrate. The methods may further include patterning a photoresist layer for high-voltage n-well regions and implanting the high-voltage n-well regions into the substrate over the p-type epitaxial layer. Each of the high-voltage n-well regions may act as an anode of the Schottky diode. The methods may further include patterning a photoresist layer for n-type well regions and implanting an n-type well region in each of the high-voltage n-well regions. The n-type well region may act as a cathode of the Schottky diode. The methods may further include forming an oxide layer regions over a portion of the substrate, forming field oxide (FOX) isolation layer regions over portions of the high-voltage n-well regions and n-well regions, and forming a gate oxide thermal layer over the substrate.

According to an aspect, part of the gate oxide thermal layer may be removed resulting in gate oxide thermal layer regions formed over portions of the substrate. A poly layer may be formed over a surface of the substrate and part of the poly layer may be removed, resulting in one or more poly field plates at least partially formed over the FOX isolation layer regions, the high-voltage n-well regions, and/or the substrate. The poly field plates are the field-plate structures operable to distribute an electric potential of the Schottky diode.

According to another aspect, a photoresist mask is provided for the p-type regions and p-type regions are implanted into the substrate between high-voltage n-well regions. The p-type regions are the p-body regions operable to pinch the current flow path in the high-voltage n-wells.

According to another aspect, a photoresist mask is provided for n-p regions, and an n-p region is implanted into the n-well regions forming an Ohmic contact for the cathode of the schottky diode. A photoresist mask is provided for p-p regions, and a p-p region is implanted into each of the p-body regions forming an Ohmic contact for the p-body regions of the Schottky diode. A dielectric layer is formed over the substrate and metal structures are formed over the dielectric providing a connection pathway for the Schottky diode.

According to another aspect, a cathode of the Schottky diode is a drain of a low-side mosfet structure, and a field-plate structure is a gate of the low-side mosfet structure, and the p-body regions operate to pinch the current flow path in the high-voltage n-wells and act as the bulk of the low-side mosfet structure.

### BRIEF DESCRIPTION OF THE DRAWINGS

FIGS. 1A and B are schematic diagrams illustrating a conventional buck-converter circuit;

FIG. 2 is a schematic diagram illustrating a formation of a schottky diode, in accordance with the present disclosure;

FIG. 3 is a schematic diagram illustrating a schottky diode, in accordance with the present disclosure;

FIGS. 4A-4C are schematic diagrams illustrating a layout and various cross sections of a schottky diode, in accordance with the present disclosure;

FIGS. 5A-5B are graphical diagrams illustrating the electrical performance of the breakdown voltage of a schottky diode, in accordance with the present disclosure;

FIG. 6 is a graphical diagram illustrating the electrical performance of the turn on voltage of a schottky diode, in accordance with the present disclosure;

FIGS. 7A-D are schematic diagrams illustrating other embodiments of schottky diodes, in accordance with the present disclosure;

FIG. 8 is a schematic diagram illustrating a layout of an embodiment of a schottky diode, in accordance with the present disclosure;

FIG. 9 is a schematic diagram illustrating a schottky diode having a metal field-plate, in accordance with the present disclosure;

FIG. 10 is a schematic diagram illustrating a schottky diode having a poly and metal field-plate, in accordance with the present disclosure;

FIGS. 11A and B are schematic diagrams illustrating variations of a schottky diode having shallow trench isolation regions or field oxide regions, in accordance with the present disclosure;

FIGS. 12A and B are schematic diagrams illustrating variations of a schottky diode having an ED structure or an LD structure, in accordance with the present disclosure;

FIG. 13 is a schematic diagram illustrating a buck converter circuit, in accordance with the present disclosure;

FIGS. 14A, B, and C are schematic diagrams illustrating a schottky diode and JFET combination, in accordance with the present disclosure;

FIGS. 15A and B are schematic diagrams illustrating a schottky diode and low-side MOSFET combination, in accordance with the present disclosure;

FIGS. 16A and B are schematic diagrams illustrating characteristics of a schottky diode and low-side MOSFET combination, in accordance with the present disclosure;

FIGS. 17A and B are schematic diagrams further illustrating a schottky diode and low-side MOSFET combination, in accordance with the present disclosure;

FIGS. 18A, B, and C are schematic diagrams illustrating an on-state MOSFET, in accordance with the present disclosure; and

FIGS. 19A and B are schematic diagrams illustrating an off-state MOSFET, in accordance with the present disclosure.

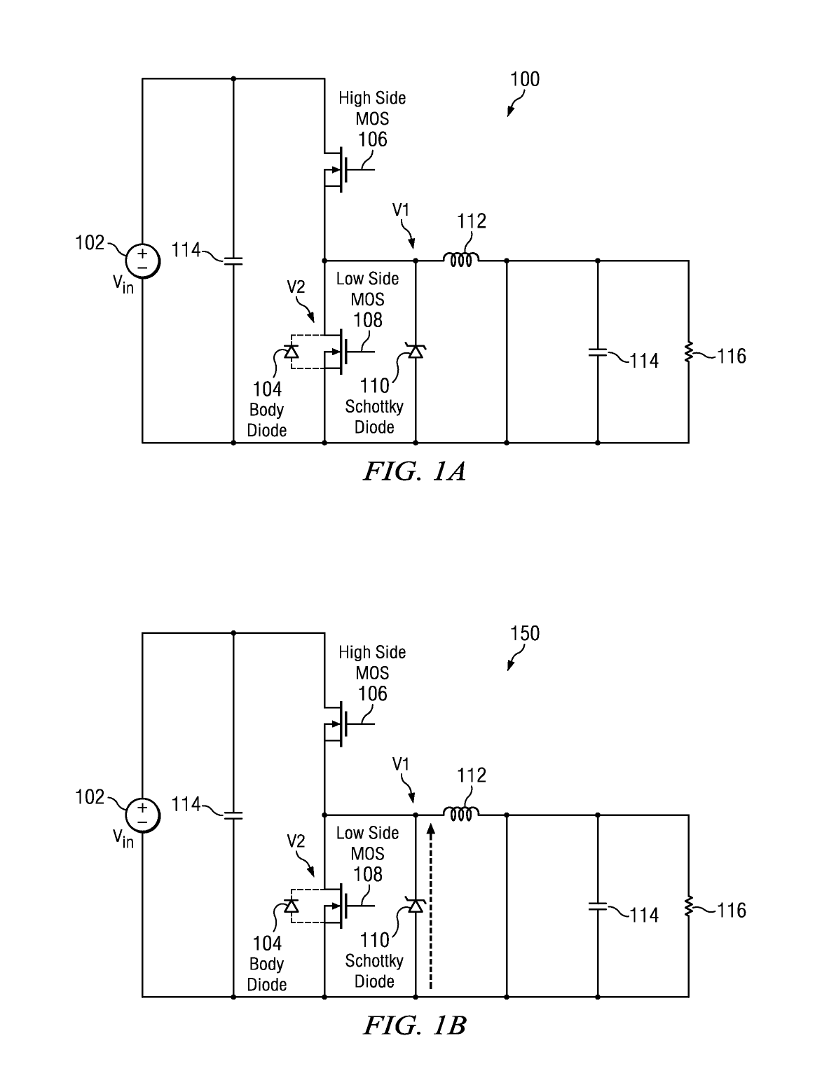

### DETAILED DESCRIPTION

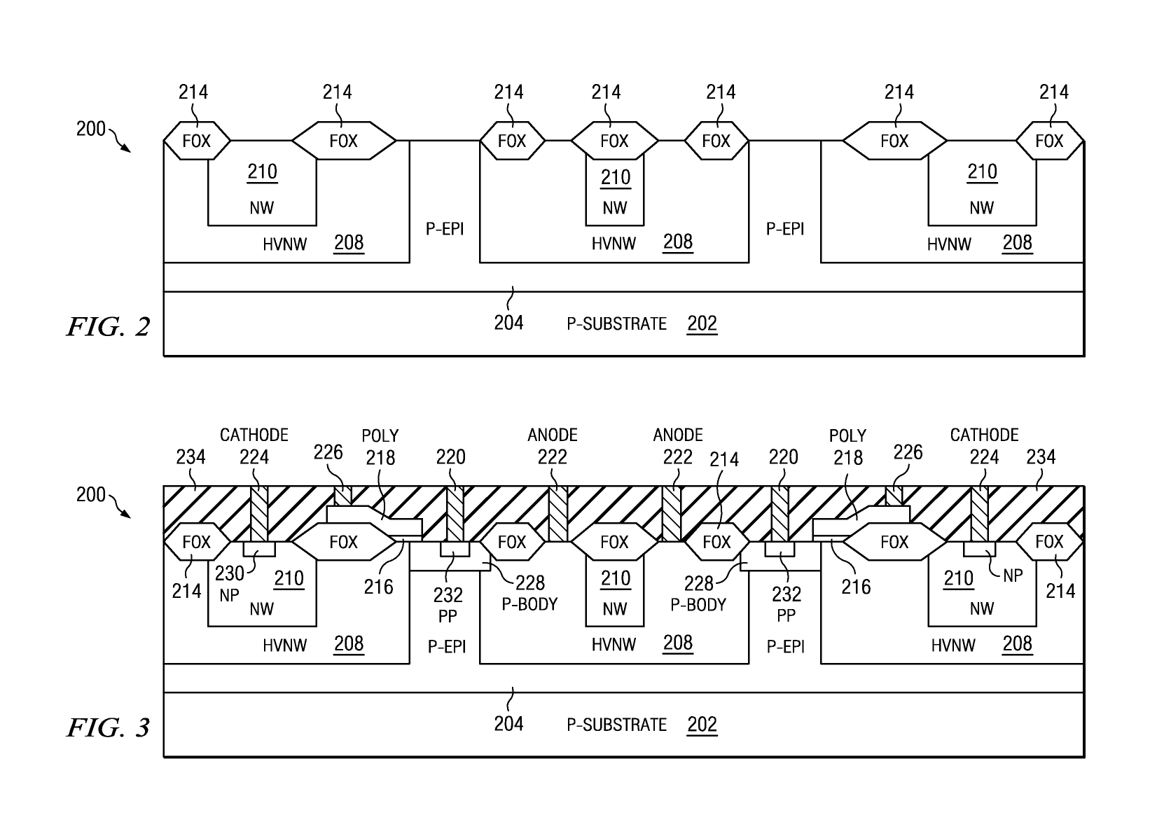

FIG. 2 is a schematic diagram illustrating formation of a schottky diode 200. A silicon wafer is provided as a substrate 202 of the schottky diode 200. A p-type epitaxial layer 204 is formed on the silicon substrate 202.

A photo resist layer is patterned to form a photo resist mask (not shown) for generating high-voltage n-well regions. High-voltage n-well regions 208 are implanted into the substrate 202 over the p-type epitaxial layer 204. Each of the high-voltage n-well regions 208 is operable as an anode of the schottky diode 200.

A photo resist layer is patterned to form a photo resist mask (not shown) for generating n-type well regions 210. An n-type well region 210 is implanted in each of the one or more high-voltage n-well regions 208. The n-type well regions 210 are each operable as a cathode of the schottky diode 200.

An oxide layer (not shown) is formed over portions of the substrate 202. A nitride film (not shown) is patterned to form a hard mask, and field oxide (FOX) isolation regions 214 are formed over portions of the high-voltage n-well regions 208 and n-well regions 210.

FIG. 3 is a schematic diagram further illustrating formation of the schottky diode 200. A gate oxide thermal layer is formed over the substrate 202, field oxide (FOX) isolation regions 214, high-voltage n-well regions 208, and n-well regions 210. Portions of the gate oxide thermal layer are removed by etching, resulting in several gate oxide thermal layer regions 216.

A poly layer is formed over a surface of the substrate 202, field oxide (FOX) isolation regions 214, high-voltage n-well regions 208, n-well regions 210, and gate oxide thermal layer regions 216. The poly layer is then partially removed, resulting in one or more poly field plates 218. In an embodiment, the poly field plates 218 are at least partially covering one or more of the field oxide (FOX) isolation layer regions 214, one or more of the high-voltage n-well regions 208, and the substrate 202.

A photo resist layer is patterned resulting in a photo resist mask (not shown) for generating one or more p-type regions. One or more p-type regions 228 are implanted into the substrate 202 between at least two high-voltage n-well regions 208, resulting in p-body regions 228. The p-type implanting is done at a high energy such that penetrating the gate oxide thermal layer regions 216 is possible.

In an embodiment, the poly field plates 218 are field-plate structures 218 operable to distribute an electric potential of the schottky diode 200. And the p-type regions 220 are p-body regions 220 operable to pinch the current flow path in the high-voltage n-wells 208.

A photo resist layer is patterned resulting in a photo resist mask (not shown) for generating n-p regions 230. One or more n-p regions 230 are implanted into the n-well regions 210. A photo resist layer is patterned resulting in a photo resist mask (not shown) for generating p-p regions 232. One or more p-p regions 232 are implanted into the p-body regions 228. Ohmic contacts 220 and 226 are formed for some of the p-p regions 232, high-voltage n-well regions 208, and field plate structures 218. The Schottky diode includes anode 222 and cathode 224 formed over high voltage n-well regions 208 and n-p regions 230, respectively. A dielectric layer 234 is formed over the field oxide (FOX) isolation layer regions 214, one or more n-well regions 210, one or more of the high-voltage n-well regions 208, n-p regions 230, field plate structures 218, gate oxide thermal layer regions 216, p-body regions 228, p-p regions 232, and the substrate 202. Metal structures (not shown) are formed over the dielectric layer 234, providing an electrical connection pathway for the schottky diode 200.

Thus, the schottky diode 200 has one or more p-body regions 228 that can pinch a current flow path in high-voltage n-well regions 208 and one or more field-plate structures 218 that can distribute an electric potential of the schottky diode 200, resulting in a higher breakdown voltage for the schottky diode 200.

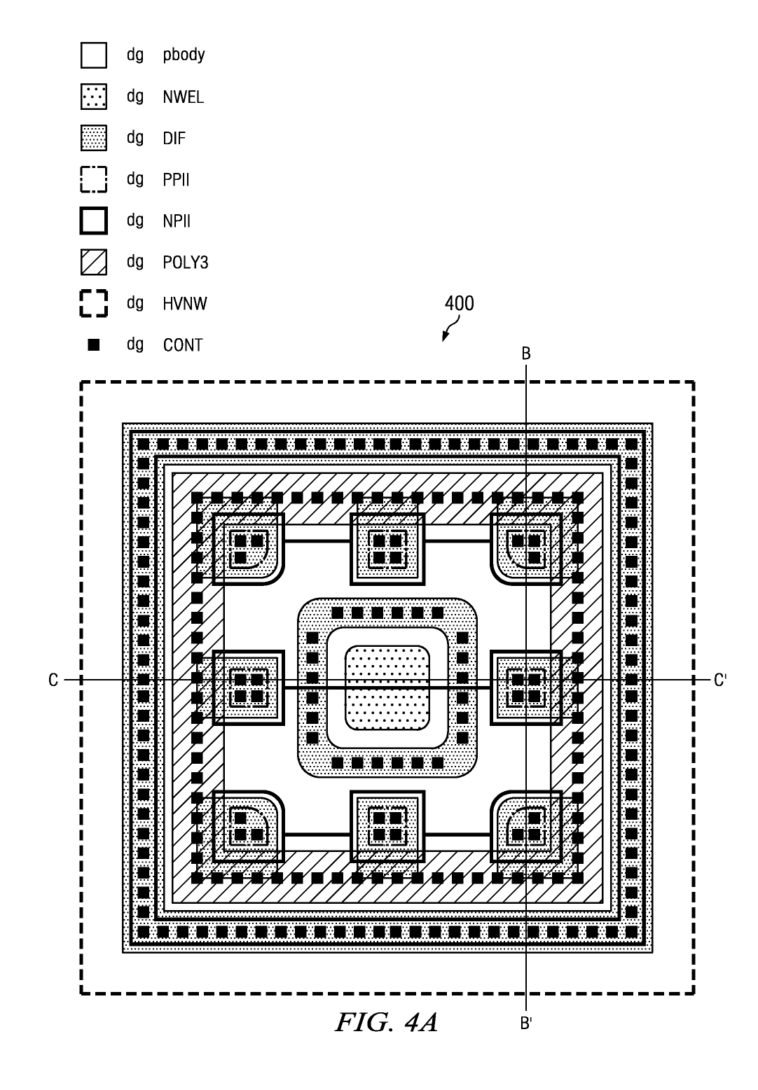

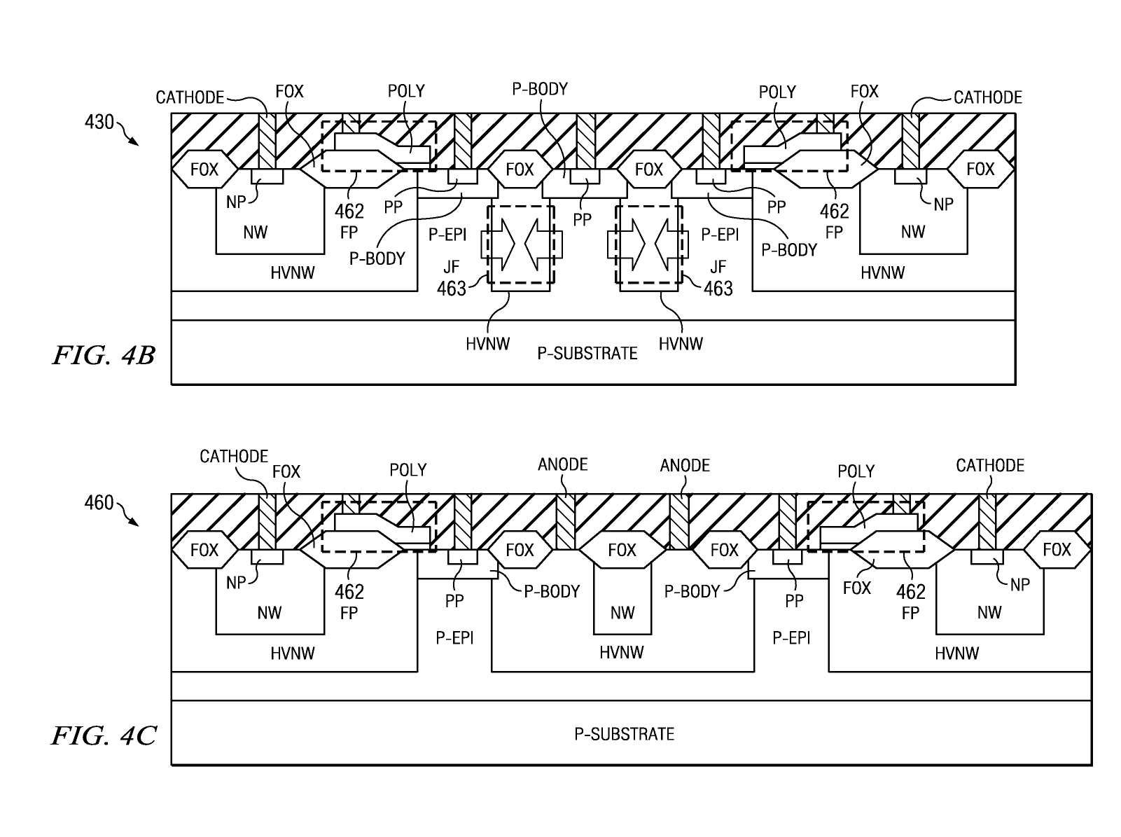

FIGS. 4A-4C are schematic diagrams illustrating a layout 400 cross sections 430, 460 of a schottky diode. Referring first to FIG. 4A, the layout 400 shows the various regions of the schottky diode, including the p-body regions, n-type wells, diffusion region, p-p regions, n-p regions, poly layer, high-voltage n-well regions, and Ohmic contacts, which are discussed above in relation to FIGS. 2 and 3. Cross sections B-B′ and C-C′ correspond to cross sections 430, 460 of FIGS. 4B and 4C, respectively.

FIG. 4B shows the cross section 430 (or cross section B-B′ of FIG. 4A). Cross section 430 shows both the one or more p-body regions operable to pinch a current flow path in high-voltage n-well regions (see, e.g. 463) and one or more field-plate structures that can distribute an electric potential of the schottky diode (see, e.g. 462), providing for a higher breakdown voltage for the schottky diode. The pinching mechanism 463 is similar to a pinch-off mechanism of a JFET, and allows the schottky diode to achieve the feature of low leakage current and higher breakdown voltage.

FIG. 4C shows the cross section 460 (or cross section C-C′ of FIG. 4A). Cross section 460 shows one or more field-plate structures that can distribute an electric potential of the schottky diode (see, e.g. 462), providing for a higher breakdown voltage for the schottky diode.

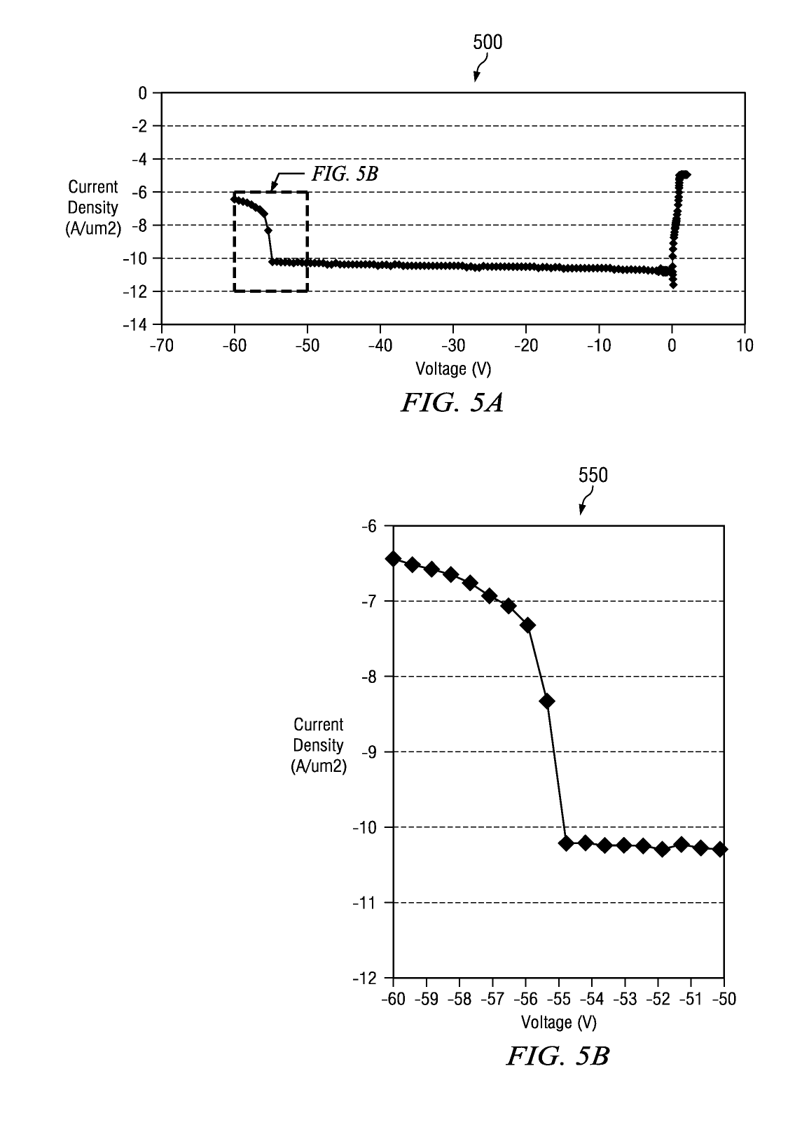

FIG. 5A is a graphical diagram 500 illustrating the electrical performance of the breakdown voltage of a schottky diode. FIG. 5B is a graphical diagram illustrating a zoomed portion 550 of the graphical diagram 500. The zoomed portion 550 highlights the an embodiment of a schottky diode having a breakdown voltage of around 55 volts, illustrating a higher breakdown voltage than conventional PN junction diode.

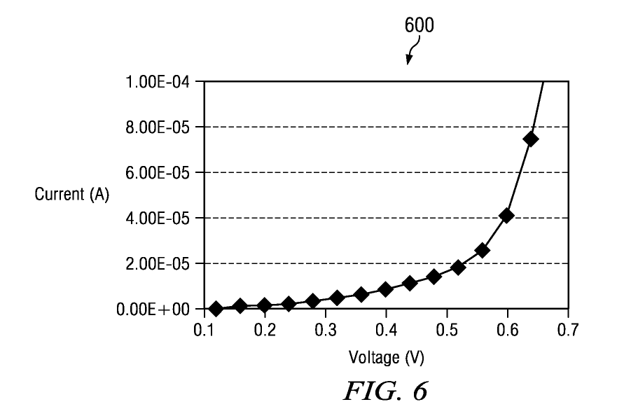

FIG. 6 is a graphical diagram 600 illustrating the electrical performance of the turn on voltage of a schottky diode. In an embodiment, the turn on voltage is relatively low compared to a conventional schottky diode, and the low turn on voltage is around 0.5 volts.

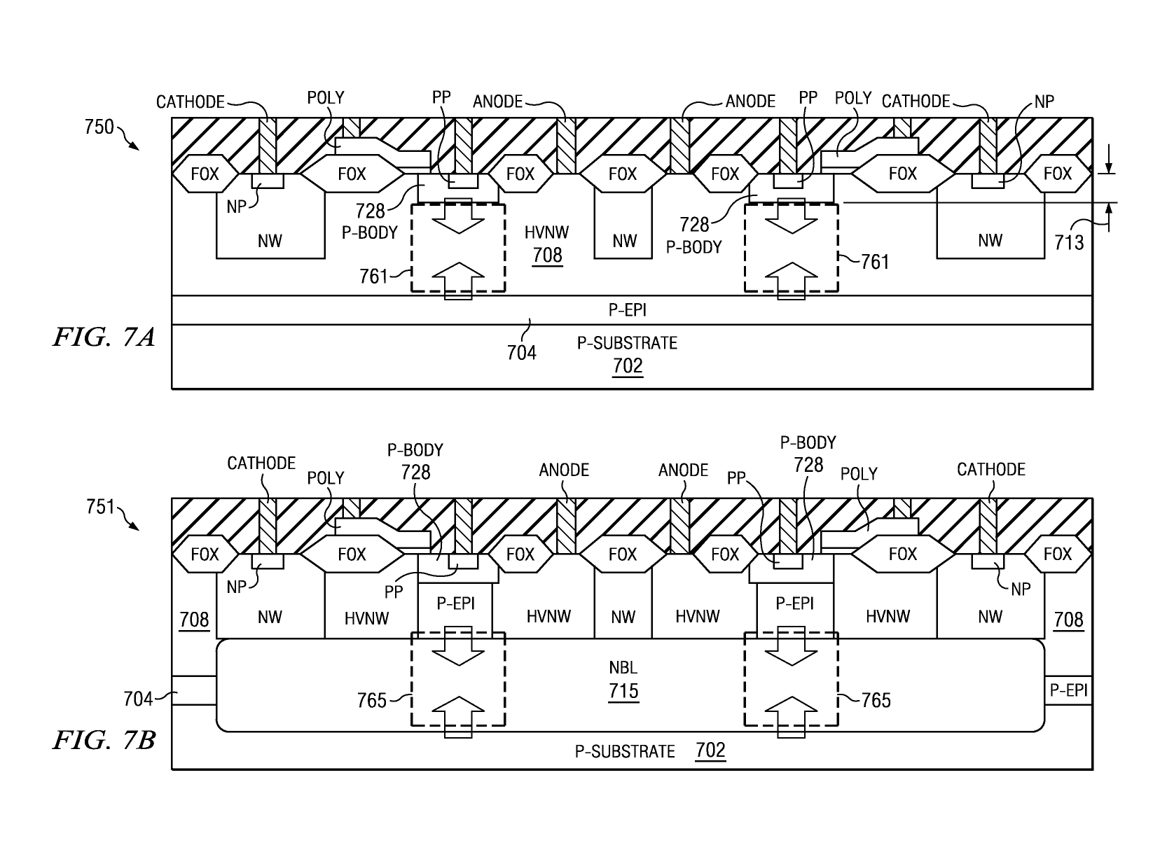

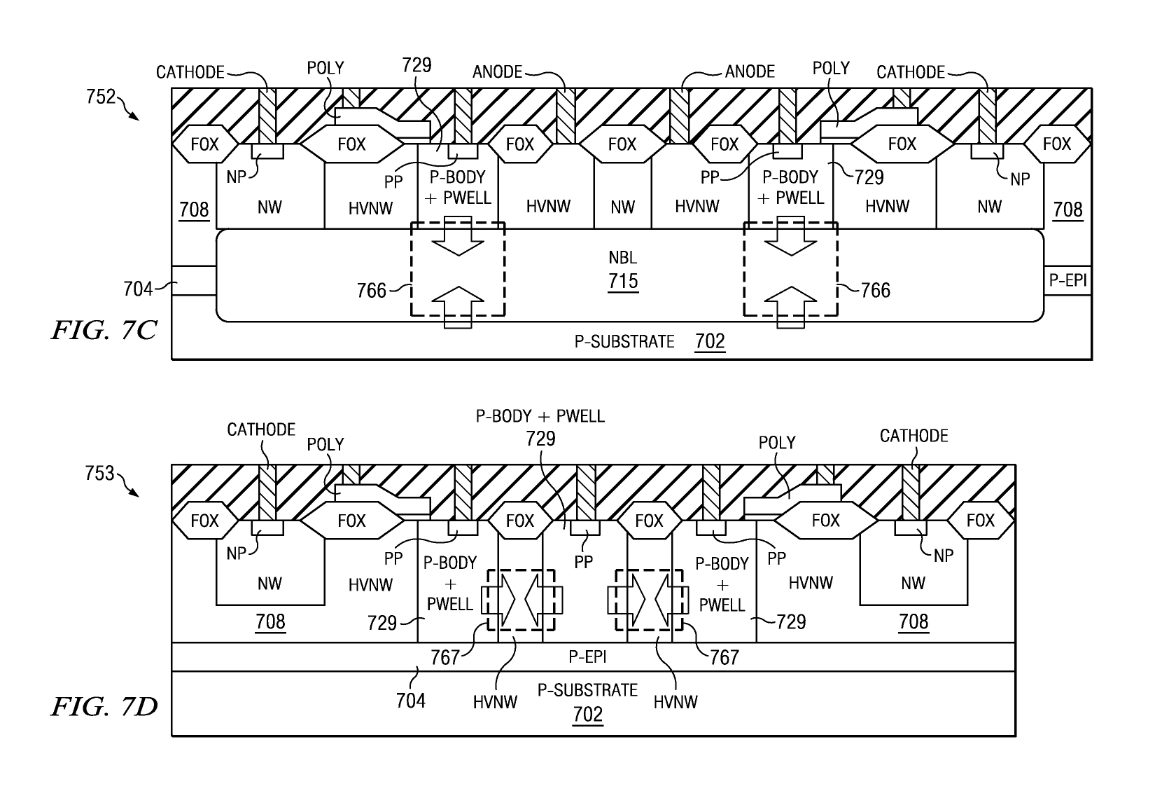

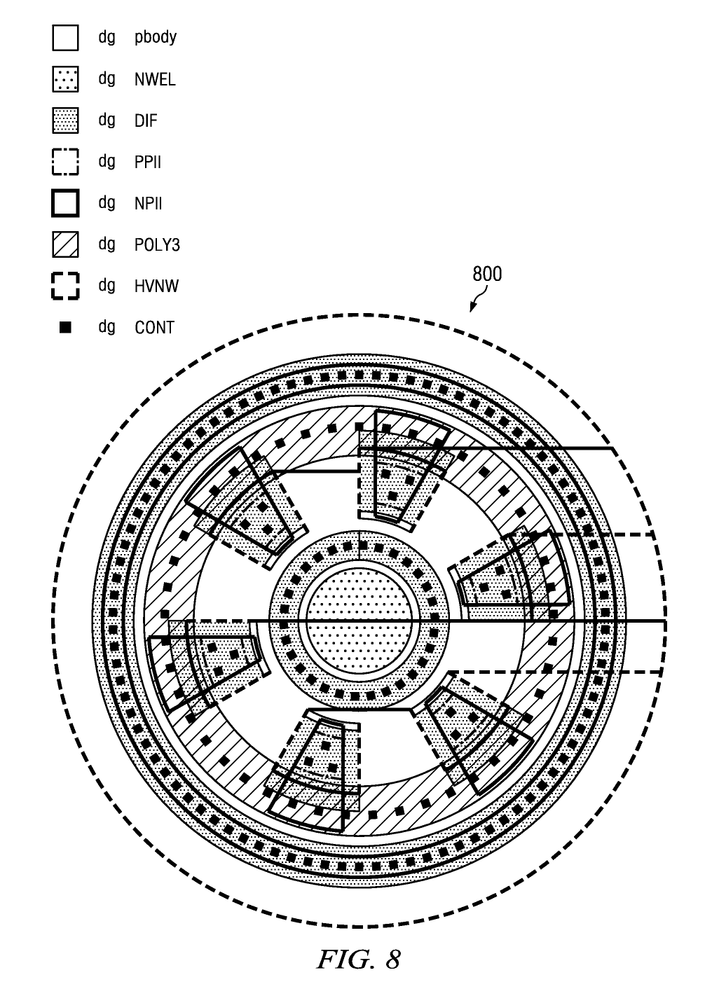

FIGS. 7A-D are schematic diagrams illustrating various embodiments of schottky diodes having an enhanced breakdown voltage. Referring to the embodiment of FIG. 7A, a schottky diode 750 is formed on p-type substrate 702. The p-body regions 728 extend down to a p-body region depth 713, the high-voltage n-well region 708 substantially surrounds the p-body regions 728, resulting in a vertical pinching mechanism 761 between the p-body regions 728 and the p-type epitaxial layer 704. Thus, the vertical pinching mechanism 761 pinches a portion of the high-voltage n-well regions between the p-body regions 728 and the p-type epitaxial layer 704.

Referring to the embodiment of FIG. 7B, a schottky diode 751 is formed on p-type substrate 702. An n-type buried layer (NBL) 715 is formed over a portion of the p-type epitaxial layer 704. The p-body regions 728 extend down to the n-type buried layer (NBL) 715, resulting in a vertical pinching mechanism 765 between the p-body regions 728 and the p-type substrate 702. Thus, the vertical pinching mechanism 765 pinches a portion of the p-body regions 728 and the n-type buried layer (NBL) 715.

Referring to the embodiment of FIG. 7C, a schottky diode 752 is formed on a p-type substrate 702. An n-type buried layer (NBL) 715 is formed over a portion of the p-type epitaxial layer 704. One or more p-body and p-type well regions 729 are formed between the high voltage n-well regions 708 over a center portion of the n-type buried layer (NBL) 715, resulting in a vertical pinching mechanism 766 between the p-type well 729 and the p-type epitaxial layer 704. Thus, the vertical pinching mechanism 766 pinches the n-type buried layer (NBL) 715.

Referring to the embodiment of FIG. 7D, the schottky diode 753 is formed on a p-type substrate 702. One or more p-body and p-type well regions 729 are formed between the high voltage n-well regions 708 over the substrate 702, resulting in a lateral pinching mechanism 767 between the one or more p-body and p-type well regions 729. Thus, the lateral pinching mechanism 767 pinches the high-voltage n-well regions 708.

Thus, a variety of mechanisms and configurations may be used to achieve the pinching mechanism of the schottky diode with enhanced breakdown. A p-body region (and/or other p-type well region) and an n-type current path combined may be used to realize the pinching mechanism concept, whether the direction of pinching be vertical or lateral across the n-type current path.

FIG. 8 is a schematic diagram illustrating an alternative layout 800 of a schottky diode with enhanced breakdown voltage. For example, the layout 800 may be a circular layout. The layout of the schottky diode with enhanced breakdown voltage should not be limited to circular or rectangular layouts, and a number of other shapes may be used.

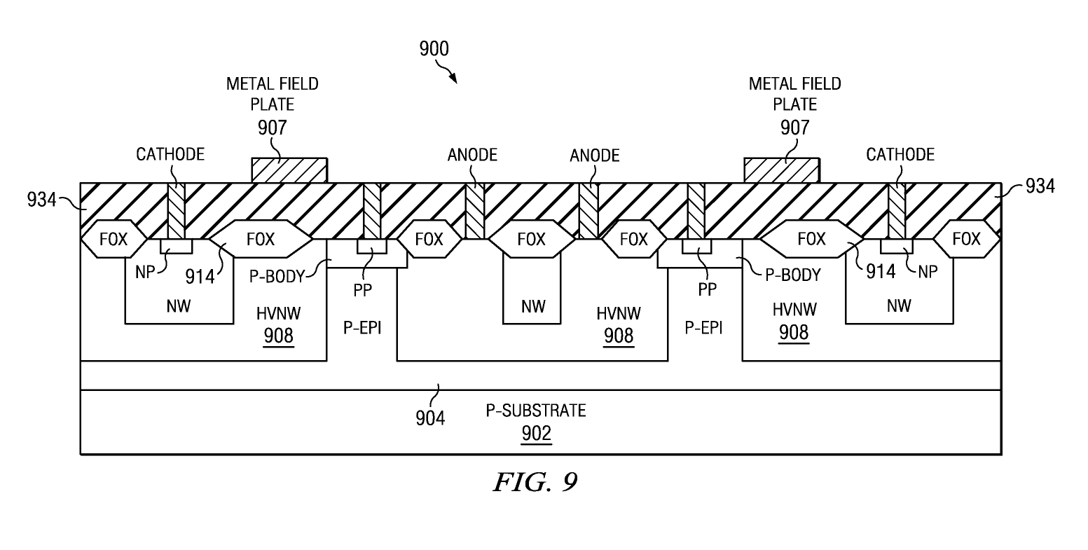

FIG. 9 is a schematic diagram illustrating an alternative embodiment of a schottky diode 900 having a metal field-plate 907 over portions of the dielectric layer 934 instead of the poly field plate structure discussed above. The metal field-plates 907 are positioned over a portion of one or more of the field oxide (FOX) isolation regions 914 and high-voltage n-type wells 908. The substrate and epitaxial layers are not shown. The metal field-pates 907 may distribute an electric potential of the schottky diode 900, resulting in a higher breakdown voltage for the schottky diode 900. In an embodiment, the metal field plates 907 may be made of a metal silicide poly material.

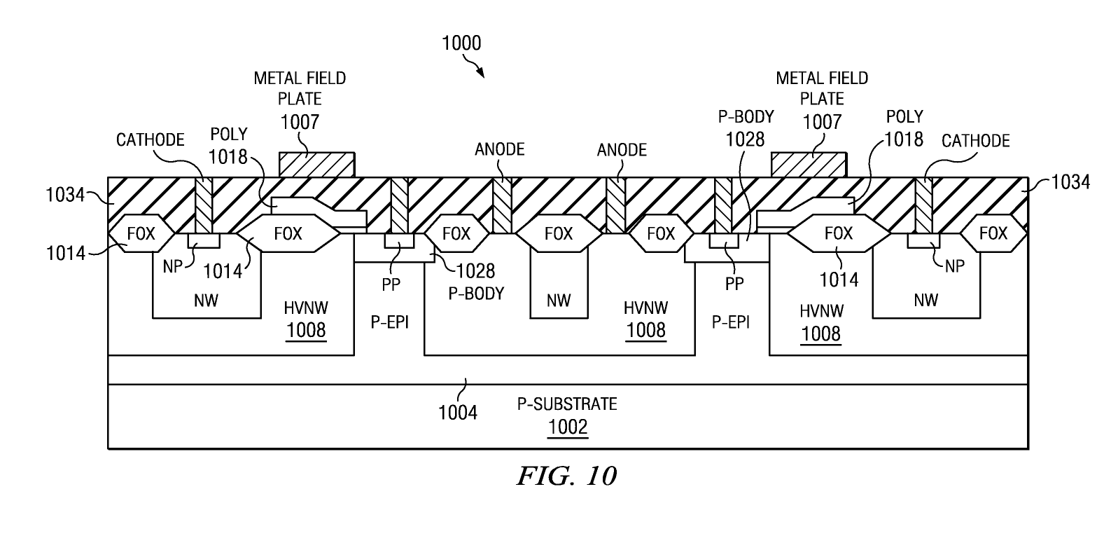

FIG. 10 is a schematic diagram illustrating another embodiment of a schottky diode 1000 having both a poly field plate structure 1018 and metal field-plate 1007. Both the poly and the metal field-plate structures 1018, 1007 may be positioned over a portion of one or more of the field oxide (FOX) isolation regions 1014 and high-voltage n-type wells 1008. The poly filed plate structure 1018 may also be positioned over a portion of one or more of the p-body regions 1028. The substrate and epitaxial layers are not shown. The metal field-pates 1007 and poly field plate structures 1018 may distribute an electric potential of the schottky diode 1000, resulting in a higher breakdown voltage for the schottky diode 1000. The dielectric layer 1034 is positioned between the metal field plates 1007 and the poly field plates 1018. In an embodiment, the metal field plates 907 may be made of a metal silicide poly material.

Thus, to achieve the field-plate effect of distributing the electronic potential of the schottky diode, metal silicide poly field plates, poly field plates, or a combination thereof, may be used.

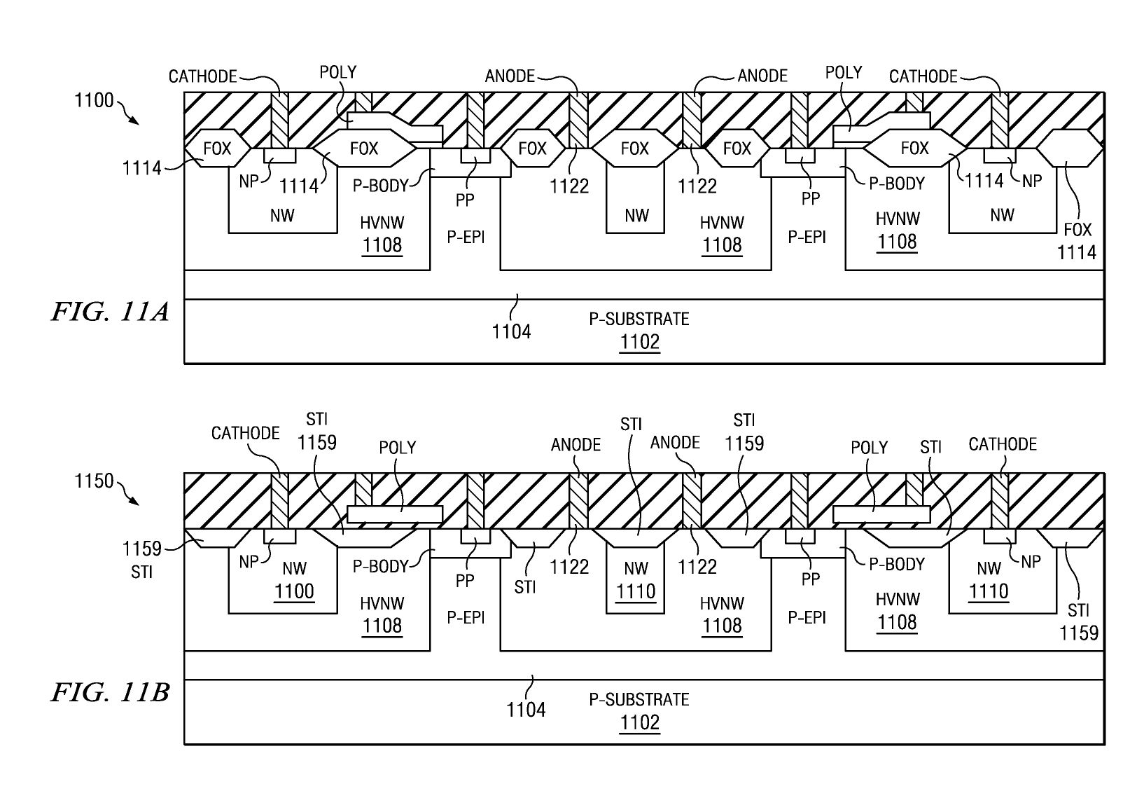

FIGS. 11A and 11B are schematic diagrams illustrating that shallow trench isolation (STI) regions 1159 (e.g., shown in FIG. 11B) may replace the field oxide (FOX) isolation regions 1114 (e.g., shown in FIG. 11A) of the schottky diode with an enhanced breakdown voltage. The schottky diode 1100 comprises the field oxide (FOX) isolation regions 1114, while the schottky diode 1150 comprises the shallow trench isolation (STI) regions 1159.

In either of the embodiments, either the field oxide (FOX) isolation regions 1114 or the shallow trench isolation (STI) regions 1159 may be positioned adjacent to and on either side of an n-type well region 1110 associated with an n-p region. The field oxide (FOX) isolation regions 1114 or the shallow trench isolation (STI) regions 1159 may also be positioned on either side of and over an n-type well region 1110 that is positioned between two anodes 1122.

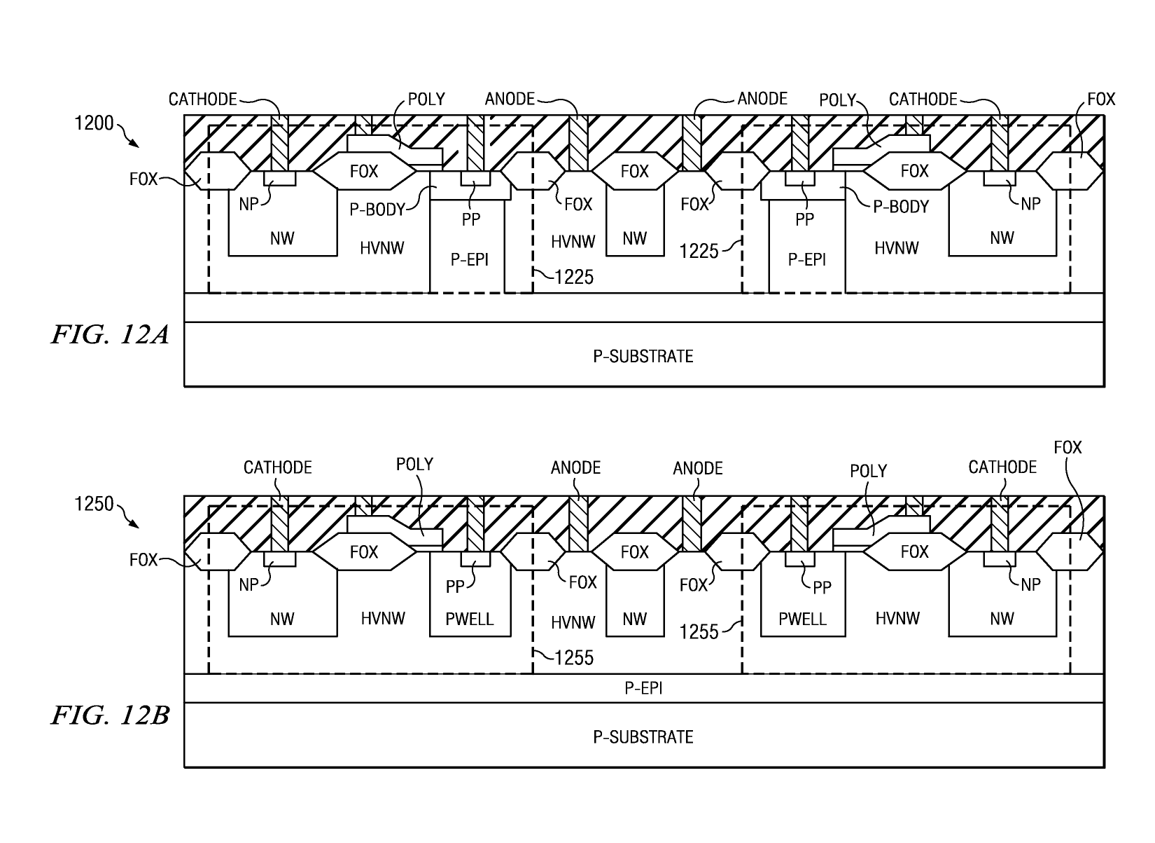

FIGS. 12A and 12B are schematic diagrams illustrating that an ED-structure 1255 (e.g., shown in FIG. 12B) may replace an LD-structure 1225 (e.g., shown in FIG. 12A) of the schottky diode with an enhanced breakdown voltage. For example, the schottky diode 1250 having an ED-structure 1255 (e.g., shown in FIG. 12B) in the place of the LD-structure 1225 of the schottky diode 1200 (e.g., shown in FIG. 12A), to take advantage of the performance of the device.

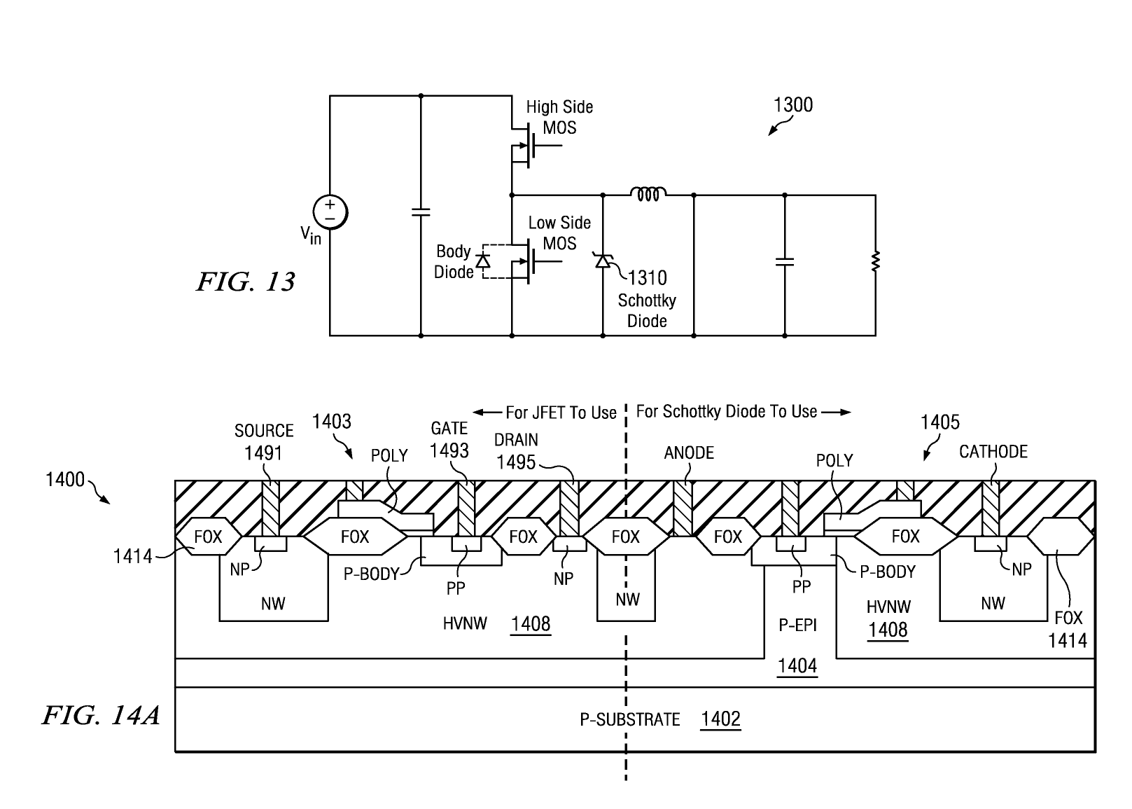

FIG. 13 is a schematic diagram illustrating a buck converter circuit 1300 having a schottky diode 1310 with an enhanced breakdown voltage. Thus, the schottky diode 1310 may be integrated into a buck converter circuit 1300. The buck converter circuit 1300 may be used in switch mode power supply (SMPS) topologies and may be used to provide a different power supply for different parts. The schottky diode 1310 with the enhanced breakdown voltage enables the buck convertor circuit 1300 to provide power at a variety of levels.

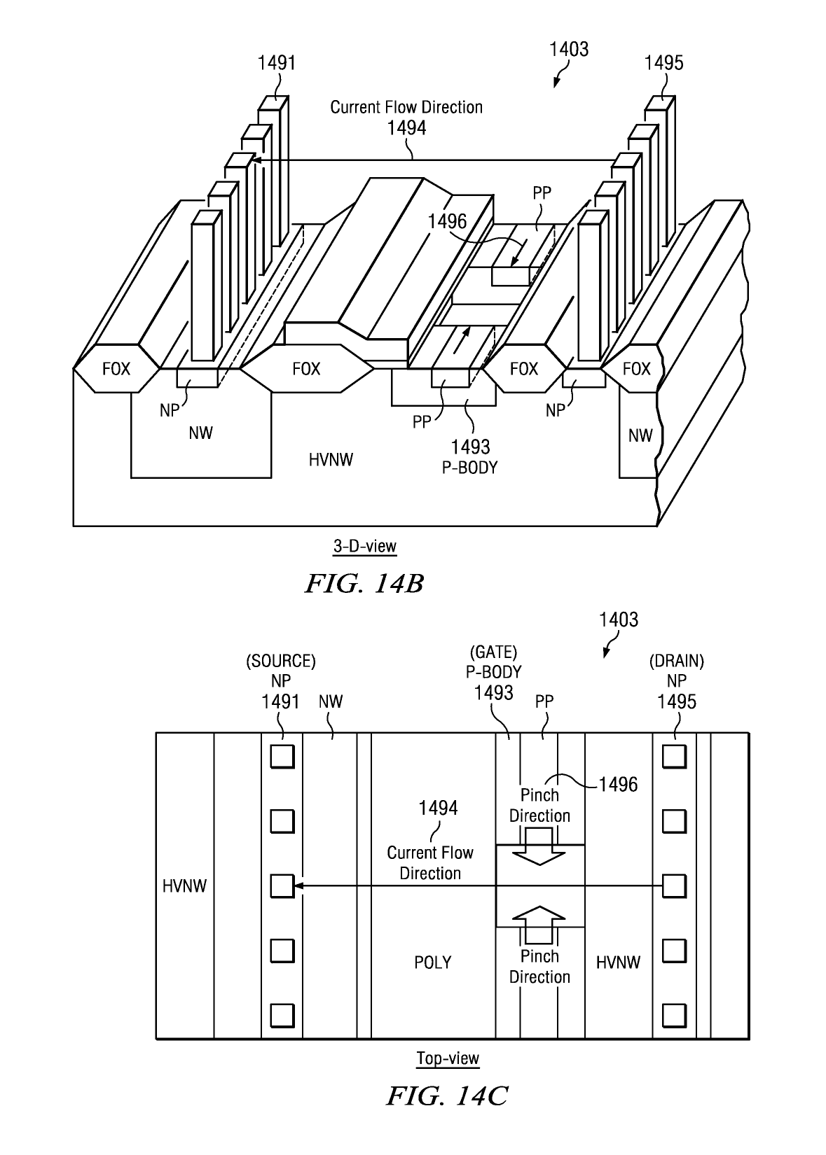

FIG. 14A is a schematic diagram illustrating a schottky diode and JFET combination device 1400. The device 1400 includes a JFET component 1403 and a schottky diode component 1405. The JFET component 1403 is made by adapting one or more of the cathodes, p-body Ohmic contacts of the proposed Schottky design to acting as a source 1491 and gate 1493 of a JFET, respectively, and by adding an N-P region 1497 between two field oxide (FOX) isolation regions 1414 and connecting an Ohmic contact to act as a drain 1495 of the JFET component 1403. FIG. 14B is a three-dimensional view of the JFET component 1403, and FIG. 14C is a top-down view of the JFET component 1403, both illustrating the current flow direction 1494 and pinch direction 1496 of the JFET component 1403.

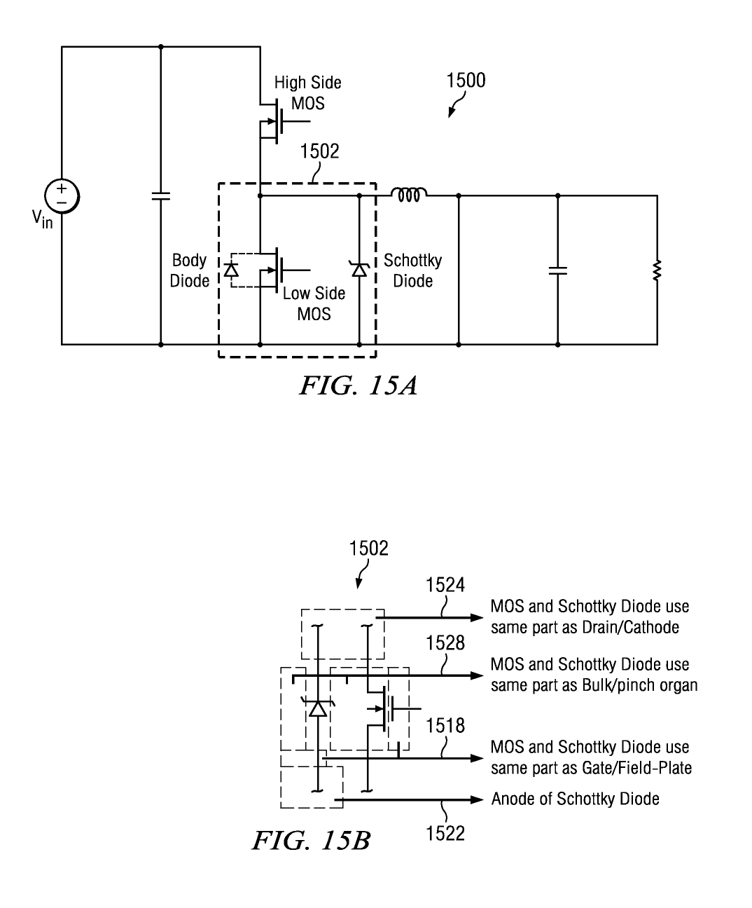

FIG. 15A is a schematic diagram illustrating a device 1500 having the schottky diode and low-side MOSFET combination 1502 on a single chip. FIG. 15B is a schematic diagram further illustrating the low-side MOSFET and schottky diode combination 1502. Combining the low-side MOSFET with the schottky diode decreases the area both elements will consume in a circuit design. This allows the proposed schottky diode with enhanced breakdown voltage to be applied in more scenarios. For example, the MOSFET and schottky diode combination 1502 may share a drain/cathode 1524, bulk/pinch organ 1528, and gate/field-plate structure 1518. The anode 1522 of the schottky diode is also shown.

Thus, a schottky diode with enhanced breakdown voltage may have a cathode that functions as a drain of the low-side mosfet structure, may have a field-plate structure that functions as a gate of the low-side mosfet structure, and may have p-body regions that are operable to pinch the current flow path in the high-voltage n-wells that further function as the bulk of the low-side mosfet structure.

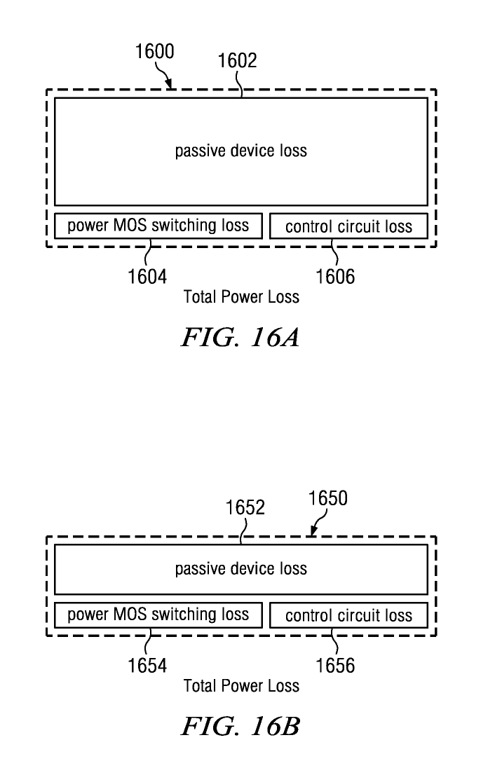

FIGS. 16A and 16B are schematic diagrams illustrating characteristics of a schottky diode and low-side MOSFET combination. The power loss of a DC-DC converter can be divided into three parts—the power MOS switching loss, the DC-DC control circuit loss, and the passive device power loss. Often the passive device power loss can dominate the total power loss, but combining the Schottky diode with the low-side MOS (and body diode) enhances the frequency, which decreases the total loss tremendously. Referring now to FIG. 16A, total power loss 1600 of a conventional DC-DC converter circuit includes the passive device loss 1602, power MOS switching loss 1604 and control circuit loss 1606 of a conventional DC-DC converter. Referring now to FIG. 16B, the total power loss 1650 of a DC-DC converter circuit with a schottky diode operating at higher frequency is substantially less than that of a conventional DC-DC converter circuit because the total power loss 1650 includes less passive device loss 1652, power MOS switching loss 1654, and control circuit loss 1656.

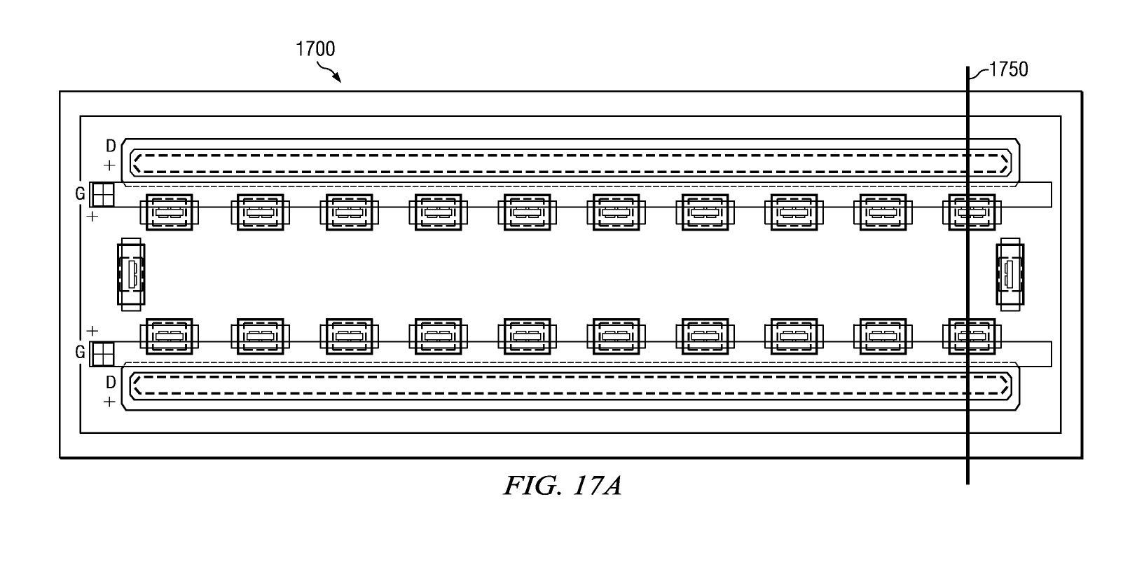

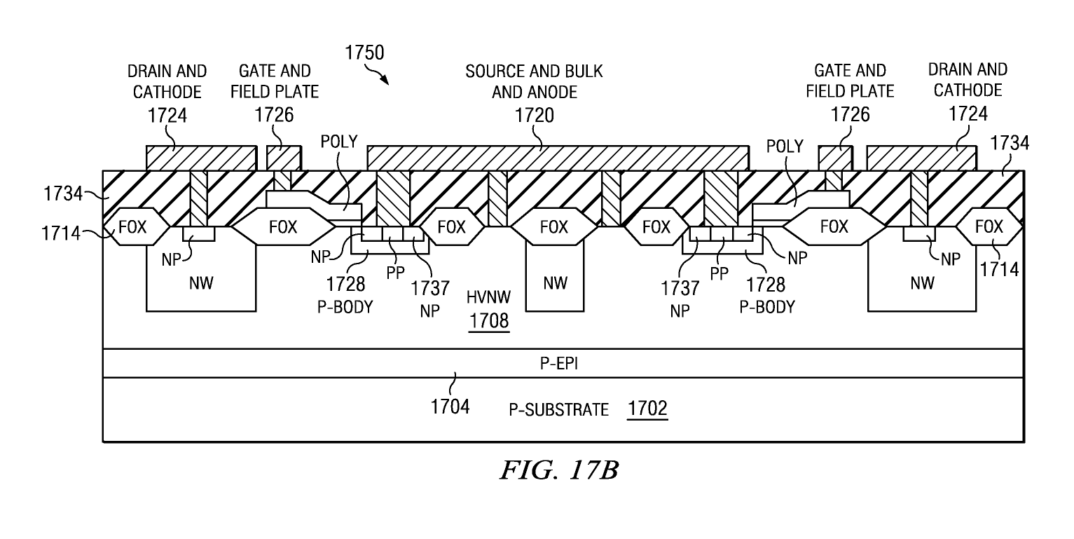

FIG. 17A is a schematic diagram further illustrating a circuit layout 1700 of a schottky diode and low-side MOSFET combination. The circuit layout 1700 has a cross section 1750, and FIG. 17B is a schematic diagram illustrating the cross section view 1750. The combination includes similar elements discussed above in relation to FIGS. 2-3, but the cathode 1724 of the schottky diode also acts as a drain of the MOSFET, the field-plate structure Ohmic connection 1726 of the schottky diode also acts as a gate of the MOSFET, and the p-body connection or anode 1720 of the schottky diode also acts as the bulk of the MOSFET. Further, the layout 1700 includes one or more n-p regions 1737 implanted into one or more of the p-body regions 1728. An Ohmic contact is provided as a connection to the new n-p region 1737, which acts as a source 1720 for the MOSFET.

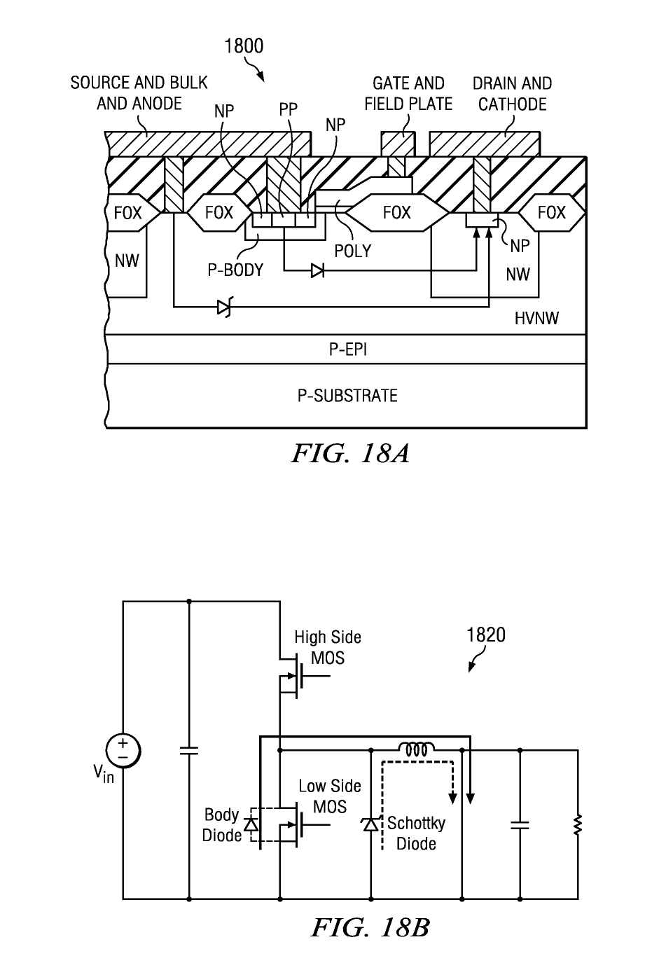

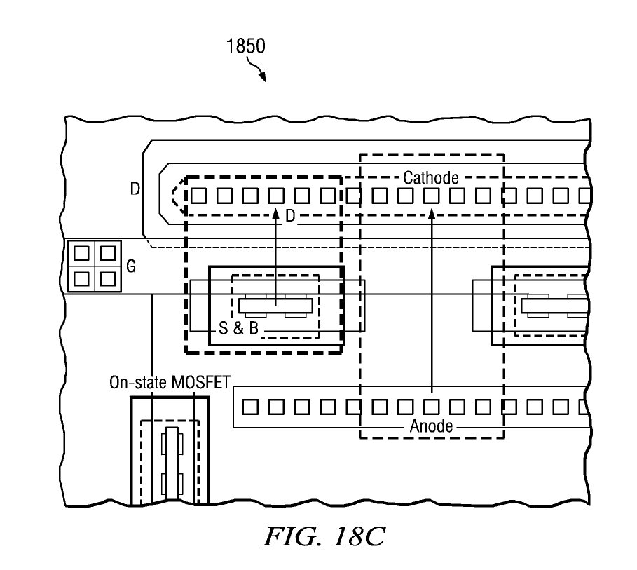

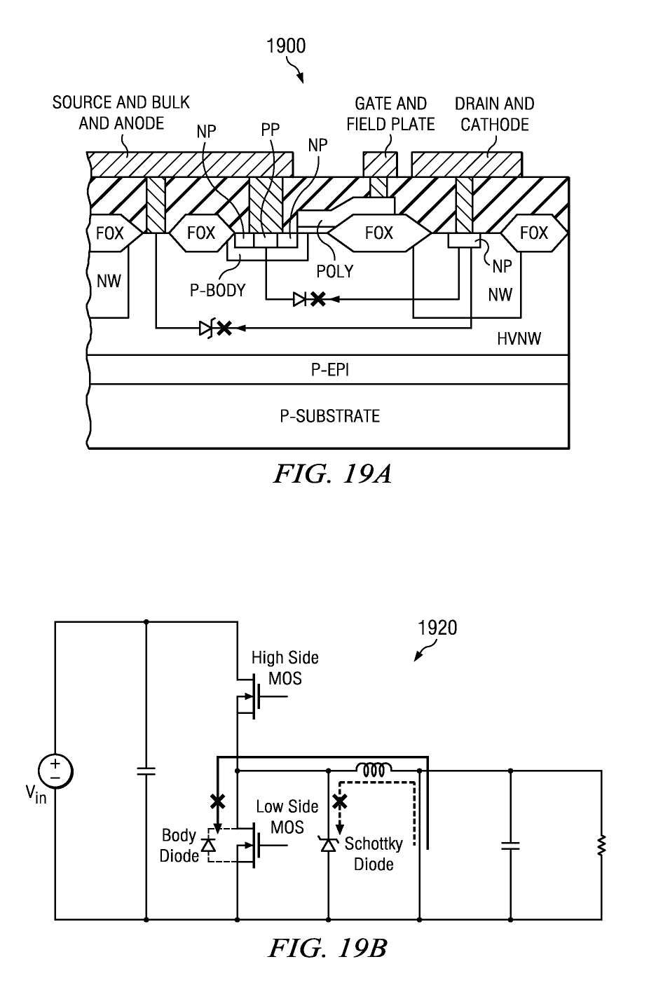

FIGS. 18A, 18B, and 18C are a schematic diagrams illustrating cross section view 1800 of an on-state MOSFET, a circuit schematic 1820 of the on-state MOSFET, and a circuit layout 1850 of the on-state MOSFET, respectively. And FIGS. 19A and 19B are a cross section view 1900 of an off-state MOSFET and a circuit schematic 1920 of the off-state MOSFET, respectively. Referring now to FIGS. 19A and 19B, when the circuit is in an off-state (state 1900, 1920), the body diode and schottky diode block the current substantially simultaneously. Referring now to FIGS. 18A, 18B, and 18C, when the circuit is in an on-state (state 1800, 1820, 1850), the body diode and schottky diode conduct the current substantially simultaneously.

While various embodiments in accordance with the disclosed principles have been described above, it should be understood that they have been presented by way of example only, and are not limiting. Thus, the breadth and scope of the invention(s) should not be limited by any of the above-described exemplary embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

What is claimed is:

1. A schottky diode, comprising:
one or more p-body regions operable to pinch a current flow path in high-voltage n-well regions; and
one or more field-plate structures operable to distribute an electric potential of the schottky diode.

2. The schottky diode of claim 1, further comprising:
a silicon substrate; and
a p-type epitaxial layer formed at a first depth of the silicon substrate.

3. The schottky diode of claim 2, further comprising one or more of the high-voltage n-well regions implanted in the substrate over the p-type epitaxial layer, wherein each of the high-voltage n-well regions comprise an anode of the schottky diode.

4. The schottky diode of claim 3, further comprising an n-type well region implanted in each of the one or more high-voltage n-well regions, the n-type well regions comprising cathodes of the schottky diode.

5. The schottky diode of claim 4, further comprising oxide layer regions formed over a portion of the substrate.

6. The schottky diode of claim 5, further comprising field oxide (FOX) isolation layer regions formed over portions of the high-voltage n-well regions and n-well regions.

7. The schottky diode of claim 6, further comprising a gate oxide thermal layer regions formed over portions of the substrate.

8. The schottky diode of claim 7, further comprising one or more poly field plates at least partially formed over one or more of the FOX isolation layer regions, one or more of the high-voltage n-well regions, and the substrate, wherein the poly field plates comprise the one or more field-plate structures operable to distribute an electric potential of the schottky diode.

9. The schottky diode of claim 8, further comprising one or more p-type regions implanted into the substrate between at least two high-voltage n-well regions, wherein the p-type regions comprise the p-body regions operable to pinch the current flow path in the high-voltage n-wells.

10. The schottky diode of claim 9, further comprising:
an n-p region implanted into each of the n-well regions, forming an Ohmic contact for the cathode of the schottky diode;
a p-p region implanted into each of the p-body regions, forming an Ohmic contact for the p-body regions of the schottky diode;
a dielectric layer formed over the substrate; and
metal structures formed over the dielectric providing a connection pathway for the schottky diode.

11. The schottky diode of claim 10, further comprising a low-side mosfet structure.

12. The schottky diode of claim 11, wherein a cathode of the schottky diode comprises a drain of the low-side mosfet structure, and wherein a field-plate structure comprises a gate of the low-side mosfet structure, and wherein the p-body regions operable to pinch the current flow path in the high-voltage n-wells comprise the bulk of the low-side mosfet structure.

13. A method for manufacturing a schottky diode having one or more p-body regions operable to pinch a current flow path in high-voltage n-well regions and having one or more field-plate structures operable to distribute an electric potential of the schottky diode, the method comprising:
providing a silicon substrate; and
forming a p-type epitaxial layer at a first depth of the silicon substrate.

14. The method of claim 13, further comprising:
patterning a photoresist layer for high-voltage n-well regions;
implanting one or more of the high-voltage n-well regions into the substrate over the p-type epitaxial layer, wherein each of the high-voltage n-well regions comprise an anode of the schottky diode;
patterning a photoresist layer for n-type well regions; and
implanting an n-type well region in each of the one or more high-voltage n-well regions, the n-type well region comprising a cathode of the schottky diode.

15. The method of claim 14, further comprising:
forming an oxide layer regions over a portion of the substrate; and
forming field oxide (FOX) isolation layer regions over portions of the high-voltage n-well regions and n-well regions; and
forming a gate oxide thermal layer over the substrate.

16. The method of claim 15, further comprising partially removing the gate oxide thermal layer resulting in gate oxide thermal layer regions formed over portions of the substrate.

17. The method of claim 16, further comprising:
forming a poly layer over a surface of the substrate; and
partially removing the poly layer, resulting in one or more poly field plates at least partially over one or more of the FOX isolation layer regions, one or more of the high-voltage n-well regions, and the substrate, wherein the poly field plates comprise the one or more field-plate structures operable to distribute an electric potential of the schottky diode.

18. The method of claim 17, further comprising:
providing a photoresist mask for one or more p-type regions;
implanting one or more p-type regions into the substrate between at least two high-voltage n-well regions, wherein the p-type regions comprise the p-body regions operable to pinch the current flow path in the high-voltage n-wells.

19. The method of claim 18, further comprising:
providing a photoresist mask for n-p regions;
implanting an n-p region into each of the n-well regions forming an Ohmic contact for the cathode of the schottky diode;
providing a photoresist mask for p-p regions;
implanting a p-p region into each of the p-body regions forming an Ohmic contact for the p-body regions of the schottky diode;
forming a dielectric layer over the substrate; and
forming metal structures over the dielectric providing a connection pathway for the schottky diode.

20. The method of claim 19, wherein a cathode of the schottky diode comprises a drain of the low-side mosfet structure, and wherein a field-plate structure comprises a gate of the low-side mosfet structure, and wherein the p-body regions operable to pinch the current flow path in the high-voltage n-wells comprise the bulk of the low-side mosfet structure.
